(19) United States
(12) Patent Application Publication
(10) Pub. No.: US 2010/0001793 A1
(43) Pub. Date: Jan. 7, 2010

(54) HIGH EFFICIENCY MODULATING RF AMPLIFIER

(75) Inventors: Paulus Thomas Maria Van Zeijl, Eindhoven (NL); Manel Collados Asensio, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/518,160

(22) PCT Filed: Dec. 5, 2007
(86) PCT No.: PCT/IB07/54928

§ 371 Date: Jun. 8, 2009

(30) Foreign Application Priority Data
Dec. 12, 2006 (EP) 06125885.1

(51) Int. Cl. H03F 3/16

(52) U.S. Cl. 330/10; 330/277

(57) ABSTRACT

A high efficiency modulating RF amplifier (10) for amplitude modulating a signal defined by a phase information signal (1) and an envelope signal (2) comprises a power supply (30) arranged to provide an operating voltage under control of the envelope signal (2). The power supply (30) comprises a plurality of power supply stages (40) and a plurality of supply switches (50) coupled between the plurality of power supply stages (40) and the modulator (20). The power supply (30) is arranged to select one of the power supply stages (40) to provide the operating voltage under control of the envelope signal (2). The high efficiency modulator RF amplifier further comprises a modulator (20) for receiving the phase information signal (1), the envelope signal (2) and the operating voltage. The modulator (20) is arranged to provide an output signal of which an amplitude is modulated under control of the envelope signal (2).

### FIELD OF THE INVENTION

The invention relates to a high efficiency modulating RF amplifier for amplitude modulating a signal. The invention further relates to a polar transmitter comprising a high efficiency modulating RF amplifier and to a device comprising a polar transmitter.

Examples of such a device are mobile phones and wireless interfaces.

### BACKGROUND OF THE INVENTION

U.S. Pat. No. 6,816,016 discloses a polar transmitter using a high efficiency modulating RF amplifier. The high efficiency modulating RF amplifier comprises an amplifier supplied by a magnitude driver controlling the output power of the amplifier. A data signal is applied to a modulation encoder that produces magnitude and phase signals. The magnitude signal is applied to the magnitude driver, and the magnitude driver provides an operating voltage for the amplifier. The magnitude driver also receives a power control signal. In response, the magnitude driver produces an operating voltage that is applied to the amplifier. The magnitude driver comprises a series coupling of a switched mode regulator that efficiently steps down a DC voltage to a voltage that approximates a desired amplifier operating level. A linear regulator performs a filtering function on the output of the switch-mode converter. Amplitude modulation is achieved by directly or effectively varying the operating voltage on the amplifier while simultaneously achieving high efficiency in the conversion of the primary DC power to the amplitude modulated output signal. High efficiency is enhanced allowing the switch-mode DC-to-DC converter to also vary its output voltage such that the voltage drop across the linear regulator is kept at a low and relatively constant level.

It is a disadvantage that the incorporation of the power envelope modulation on the magnitude driver complicates the design since both the switched mode regulator and the linear modulator must be made responsive to the magnitude signal.

It is a further disadvantage that despite the more complicated design the efficiency enhancement is limited in case a fast changing signal such as a WLAN OFDM transmit signal needs to be amplified. The bandwidth of state of the art switched mode power supplies is not sufficient to accommodate the bandwidth requirements of standards such as a WLAN standard. Therefore in the disclosed prior art, when a burst begins, the switched mode regulator ramps up to a fixed level while the linear regulator controls a power envelope modulation during said burst. This however gives an increased power loss in the linear regulator.

### SUMMARY OF THE INVENTION

It is an object of the invention to provide a high efficiency modulating RF amplifier with a simplified design.

This object is achieved with the high efficiency modulating RF amplifier as defined in claim 1. The high efficiency modulating RF amplifier according to the invention comprises a modulator and a power supply for providing an operating voltage to the modulator. Unlike the prior art where the high efficiency modulating RF amplifier comprises an amplifier for receiving a phase information signal and a magnitude driver for modulating a operating supply voltage of the amplifier the high efficiency modulating RF amplifier according the invention comprises a modulator that receives both the envelope signal and the phase information signal and provides amplitude modulation of the output signal under control of the envelope signal. To enhance the efficiency of the modulator the operating voltage of the modulator provided by the power supply is adjusted to the amplitude of the output signal. In the invention each one of the plurality of power supply stages provides a supply voltage independent of the envelope signal. The operating voltage is selected from the plurality of power supply stages by having only one of the supply switches conducting whereby the conducting supply switch is determined by the envelope signal. Thus the design of the high efficiency modulating RF amplifier is simplified, thereby achieving the object of the invention.

A further embodiment of the high efficiency modulating RF amplifier as defined in claim 2 has the advantage that the instantaneous amplitude of the output signal is determined by a plurality of amplitude switches and a plurality of current sources under control the envelope signal. The current delivered by the current sources is in dependence of the phase information signal. The envelope signal may be a digital signal comprising a plurality of bits. Both the plurality of supply switches determining the instantaneous operating voltage and the plurality of amplitude switches are under control of one or more out of the plurality of bits thereby further simplifying the design.

In a further embodiment of the high efficiency modulating RF amplifier according to claim 3 each one of the current sources comprises a first transistor. Each first transistor provides a main current path between a first and second main electrode. Each one of the amplitude switches comprises a second transistor, whereby each second transistor provides a main current path between a first and second main electrode. Each one of the current sources is coupled through an amplitude switch to the output of the high efficiency modulating RF amplifier. By serially coupling the two main current paths of a first and a second transistor such that the two main current paths form one longer main current path a modulator has been created having an advantage that it may be designed for field effect transistor technology or may be designed for another kind of technology. A further advantage of this modulator is that it is simple thereby simplifying the design of the high efficiency modulating RF amplifier.

In a further embodiment of the high efficiency modulating RF amplifier according to claim 4 each one of the plurality of supply switches comprises a third transistor and each one of the second transistors and each one of the third transistors comprises a control electrode for receiving the envelope code. By supplying the envelope code to the control electrode of each one of the second and third transistors, the second and third transistor is given a digital switching function in a simple way.

In a further embodiment of the high efficiency modulating RF amplifier according to claim 5 each first transistor further comprises a control electrode for receiving the phase information signal. By supplying the phase information to the control electrode of each first transistor the first transistor is given a current source or an amplifying function in a simple way.

In a further embodiment of the high efficiency modulating RF amplifier according to claim 6 the first main electrode of each one of the first transistors is supplied with the phase information signal thereby giving each first transistor a current source or an amplifying function in a simple way.

In a further embodiment of the high efficiency modulating RF amplifier according to claim 7 the impedance network comprises a parallel coupling of a resistor, an inductor and a capacitor. The inductance value and the capacitance value are chosen such that the impedance network acts as a resistive pull up for a signal with frequency f₀ that is included in the phase information signal. The impedance network will attenuate signals with other frequencies than f₀. This gives the advantage that the phase information signal is filtered and the signal with frequency f₀ will have the largest amplitude at the output.

A further embodiment of the high efficiency modulating RF amplifier according to claim 8 has the advantage that the efficiency is further improved. The power supply comprises at least one power supply stage having an increased efficiency by using a switching technique. An example of such a power supply stage is a DC-DC converter.

In a further embodiment of the high efficiency modulating RF amplifier according to claim 9 the power supply comprises a boost converter. This gives the advantage that in a battery supplied application a operating supply voltage higher than the battery voltage can be provided to the modulator thereby increasing the maximal output voltage swing and output power of the high efficiency modulating RF amplifier.

The polar transmitter according to the invention is defined by comprising the high efficiency modulating RF amplifier according to the invention and comprising a circuit for generating a phase/frequency signal and the envelope signal and further comprising an oscillator for receiving the phase/frequency signal and for generating the phase information signal.

An embodiment of a polar transmitter according to claim 10 comprising the high efficiency modulating RF amplifier according to any one of claim 1-7 has the advantage of simplified design. The embodiment of a polar transmitter according to claim 10 comprising the high efficiency modulating RF amplifier according to claim 8 has a further advantage of an increased efficiency. The embodiment of a polar transmitter according to claim 10 comprising the high efficiency modulating RF amplifier according to claim 9 has a further advantage of an increased output power.

In an embodiment as claimed in claim 11 the device comprises the polar transmitter as defined in claim 9 or 10. Examples of such a device are mobile phones and wireless interfaces. As these devices may be battery powered the use of a polar transmitter with increased efficiency is advantageous for the operating time. The simplified design of the high efficiency modulating RF amplifier further provides a means for cost reduction. These and other aspects of the invention are apparent from and will be elucidated with reference to the embodiments described hereinafter.

### BRIEF DESCRIPTION OF THE DRAWINGS

In the drawings:

FIG. 1 shows schematically a polar transmitter architecture,

FIG. 2 shows schematically an embodiment of a high efficiency modulating RF amplifier according to the invention,

FIG. 3 shows schematically a transmit signal in the time domain,

FIG. 4 shows schematically a cumulative envelope distribution of the signal of FIG. 3,

FIG. 5 shows schematically a further embodiment of a high efficiency modulating RF amplifier according to the invention,

FIG. 6 shows schematically a further embodiment of a high efficiency modulating RF amplifier according to the invention,

FIG. 7 shows schematically a device according to the invention comprising a polar transmitter according to the invention.

### DETAILED DESCRIPTION OF THE EMBODIMENTS

There are several known architectures for the transmission of signals, one of them being polar transmission. With polar transmission a signal to be transmitted is represented in the form of polar signals being an envelope signal r(t) 2 and a phase information signal phi(t) 1. The envelope signal r(t₀) provides an instantaneous amplitude at t=t₀, and the phase information signal phi(t₀) gives an instantaneous phase at t=t₀. The transmitted signal may be written as

s(t)=r(t)*Re(e^{j[ω}^{₀}^{t+phi(t)]})

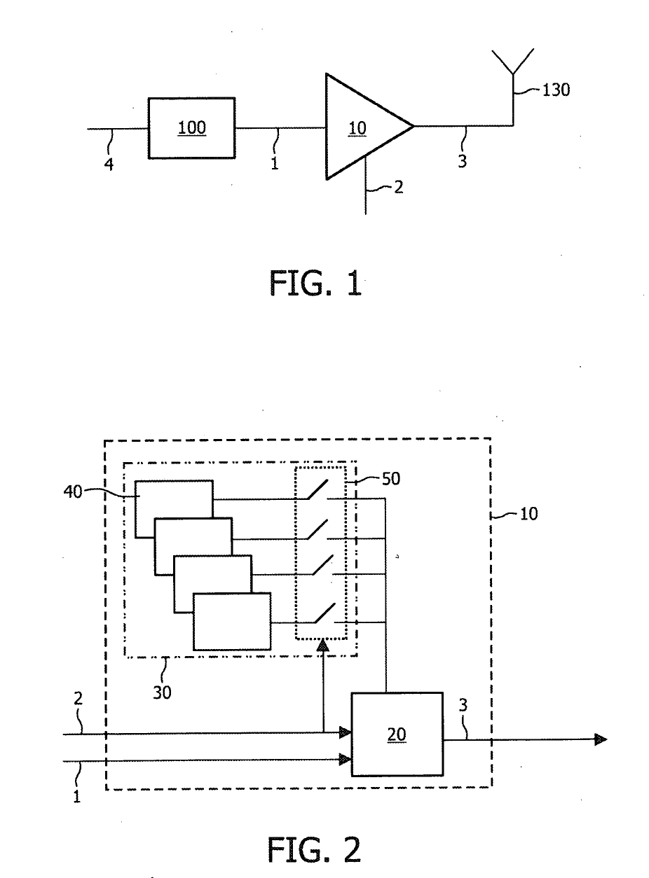

FIG. 1 shows a simplified schematic diagram of the polar transmitter architecture. The polar transmitter architecture comprises a Voltage Controlled Oscillator and/or Phase Locked Loop 100 and a modulating RF amplifier 10. By modulation of a phase signal 4 provided to the Voltage Controlled Oscillator and/or Phase Locked Loop 100 the phase information signal phi(t) 1 is obtained and coupled to an input of the modulating RF amplifier 10. The envelope signal r(t) 2 is coupled to a further input of the modulating RF amplifier. The amplitude of the phase information signal phi(t) 1 is modulated under control of the envelope signal r(t) 2 resulting in an amplitude modulated output signal that is radiated at an antenna 130.

A known way of implementing the amplitude modulation is by controlling the supply voltage of the modulating RF amplifier 10. To achieve an improved power efficiency the supply voltage may be provided by a switched mode power supply under control of the envelope signal r(t) 2. The power efficiency is defined as the ratio between the RF output power provided at an output of the RF amplifier and the input power taken from the power supply.

The high efficiency modulating RF amplifier according to the invention may be used in a polar transmitter architecture and has the advantage of a simplified design.

The applicant has recognized that since the amplitude of the transmitted signal is dependent on the envelope signal r(t) the modulating RF amplifier in FIG. 1 provides an amplitude modulating function and may be realized with a modulator of which the power efficiency may be improved, thereby providing a high efficiency modulating RF amplifier.

For increased power efficiency the modulating RF amplifier in the polar transmitter architecture may comprise:

a modulator being capable of operating at a plurality of supply voltages,

a power supply providing the plurality of supply voltages to the modulator and

means to select a supply voltage from the plurality of supply voltages in dependence of the envelope signal r(t).

FIG. 2 shows an embodiment of a high efficiency modulating RF amplifier 10 for amplitude modulating a signal defined by a phase information signal 1 and an envelope signal 2. The high efficiency modulating RF amplifier 10 comprises a power supply 30 arranged to provide an operating voltage under control of the envelope signal 2, and is characterized in that:

the high efficiency modulator RF amplifier 10 further comprises a modulator 20 for receiving the phase information signal 1, the envelope signal 2 and the operating voltage,

the modulator 20 is arranged to provide an output signal of which an amplitude is modulated under control of the envelope signal 2,

the power supply 30 comprises a plurality of power supply stages 40 and a plurality of supply switches 50 coupled between the plurality of power supply stages 40 and the modulator 20,

the power supply 30 is arranged to select one of the power supply stages 40 to provide the operating voltage under control of the envelope signal 2.

The operation of the high efficiency modulating RF amplifier 10 is explained as follows. The modulator 20 receives both the envelope signal r(t) 2 and the phase information signal phi(t) 1 and provides amplitude modulation of the output signal provided at output 3 under control of the envelope signal 2 r(t). To enhance the efficiency of the modulator 20 the operating voltage of the modulator provided by the power supply 30 is adjusted to the amplitude of the output signal. Each one of the plurality of power supply stages 40 provides a supply voltage independent of the envelope signal r(t) 2. The operating voltage is selected from the plurality of power supply stages 40 by having only one of the supply switches 50 conducting whereby the conducting supply switch 50 is determined by the envelope signal r(t) 2.

A further advantage of the high efficiency modulating RF amplifier according to the invention is that an improved power efficiency is achieved with transmitted signals that comply with a WLAN standard such as for example IEEE 802.11a.

In signals complying with a WLAN standard the transmitted power for a certain packet may be dependent on change of a channel (i.e. 802.11a), change of a country (i.e. 802.11b/g) or on the choice of a manufacturer. For the transmission of signals complying with the WLAN standard the amplitude modulation by means of controlling the supply voltage with a switched mode power supply is not possible due to the bandwidth limitations of state of the art switched mode power supplies.

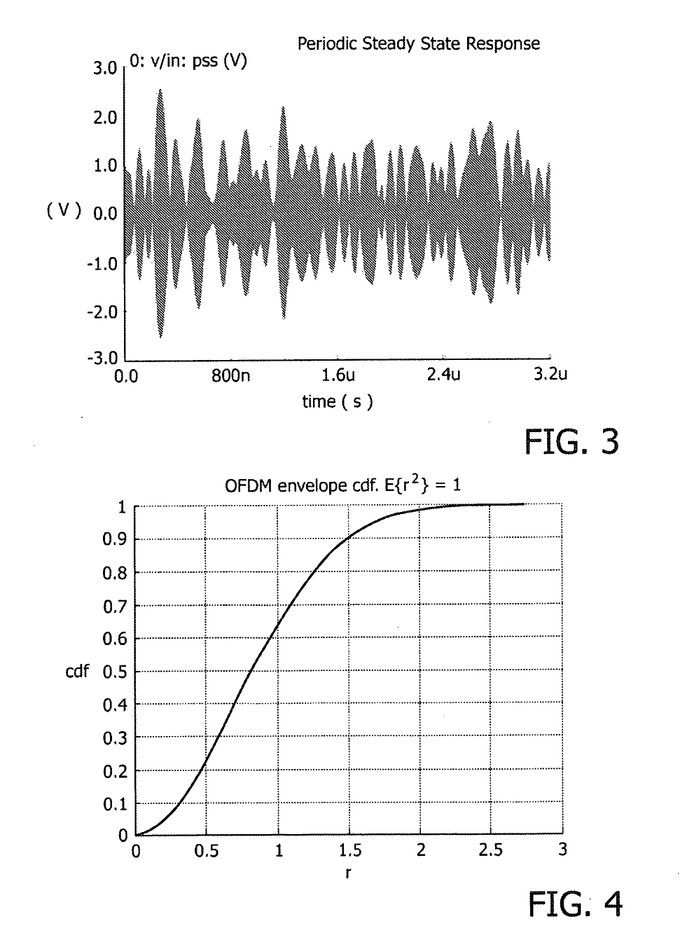

An example of a WLAN transmit signal using an OFDM modulation scheme is presented in the time domain in FIG. 3. In FIG. 4 the cumulative envelope distribution of said signal is shown. Using the cumulative envelope distribution of the WLAN OFDM transmit signal the data presented in table 1 is obtained:

TABLE 1

| Amplitude range of the amplitude | Percentage of time that r(t) is |
|---|---|
| r(t) of the transmit signal [V] | within the amplitude range |
| 0-0.8 | 45% |
| 0.8-1.6 | 45% |
| 1.6-2.4 | 9% |
| 2.4-3.2 | 1% |

According to the data of table 1 a transmitted signal being delivered by the modulating RF amplifier 10 to a load coupled to the output 3 has a large amplitude for only a small percentage of the time.

A major source of power inefficiency is power dissipated in an output stage of the RF amplifier. It is well known in the art that a major source of dissipation in the output stage is caused by the simultaneous occurrence of current through an output transistor coupled to the output 3 and a voltage across said output transistor.

Therefore the efficiency of the RF amplifier may be improved by having the voltage across the output transistor being adjusted to the amplitude of the transmit signal provided at the output. From table 1 is learned that the efficiency may be improved considerably by having a plurality of supply voltages, e.g. four, each one of the supply voltages being fit for the RF amplifier 10 to handle one of the four amplitude ranges of the amplitude of the transmit signal.

The operating voltage of the modulator 20 provided by the power supply 30 is adjusted to the envelope signal r(t) 2. It is an advantage that the power supply 30 enables a short reaction time in the order of nano-seconds for an adjustment of the operating voltage in dependence of the envelope signal r(t) 2. This enables the adjustment of the operating voltage of the modulator 20 within a short time slot such as for example a UMTS time slot that is in the order of 50 μs, thereby providing a high efficiency within said time slot.

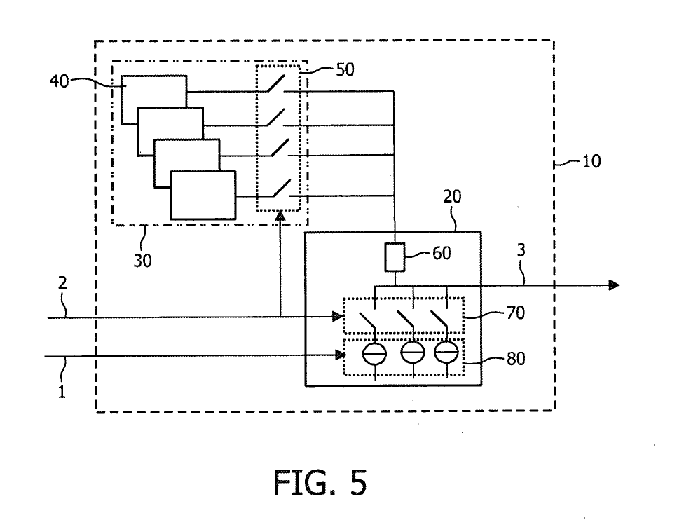

FIG. 5 shows an embodiment of the high efficiency modulating RF amplifier 10 according to claim 1 wherein the modulator 20 further comprises:

an impedance network 60 coupled between the power supply 30 and the output 3,

a plurality of amplitude switches 70 coupled between the output 3 and a plurality of current sources 80, each one of the amplitude switches 70 being under control of the envelope signal 2 and each one of the current sources 80 being arranged to provide a current in dependence of the phase information signal 1.

The instantaneous amplitude of the output signal provided at output 3 is determined by a plurality of amplitude switches 70 and a plurality of current sources 80 under control the envelope signal 2. The current delivered by the current sources 80 is in dependence of the phase information signal 1.

In this embodiment the envelope signal r(t) controls the amplitude switches 70 determining the instantaneous amplitude of the output signal provided at the output 3 as well as the operating voltage being provided to the modulator 20 by the supply switches 50. In this way within a transmit frame or packet the operating voltage is adjusted to the instantaneous amplitude of the output signal thereby increasing the power efficiency accordingly.

The envelope signal 2 may be a digital signal comprising a plurality of bits. Then both the plurality of supply switches 50 determining the instantaneous operating voltage and the plurality of amplitude switches 70 are under control of one or more out of the plurality of bits thereby further simplifying the design.

As an example suppose an 8-bit digital envelope signal b7 . . . b0, b0 being the LSB. Further suppose that the power supply 30 comprises four power supply stages 40 providing supply voltages 0.25V, 0.5V, 0.75V and 1V coupled through four supply switches 50 to the modulator 20. Then said four supply switches may be controlled by the two most significant bits of the envelope signal r(t) according to table 2 allowing simple decoding of the envelope signal to obtain drive signals for said four supply switches.

TABLE 2

| | | Operating voltage |
|---|---|---|
| b7 | b6 | provided to the modulator |
| 0 | 0 | 0.25 V |
| 0 | 1 | 0.5 V |
| 1 | 0 | 0.75 V |
| 1 | 1 | 1.0 V |

It is an advantage that unlike prior art no envelope detector and supply modulator are required. In the application the information obtained from the digital envelope signal 2 is decoded with simple logic to obtain drive signals for the plurality of supply switches 50. This simplifies the design of the high efficiency modulating RF amplifier.

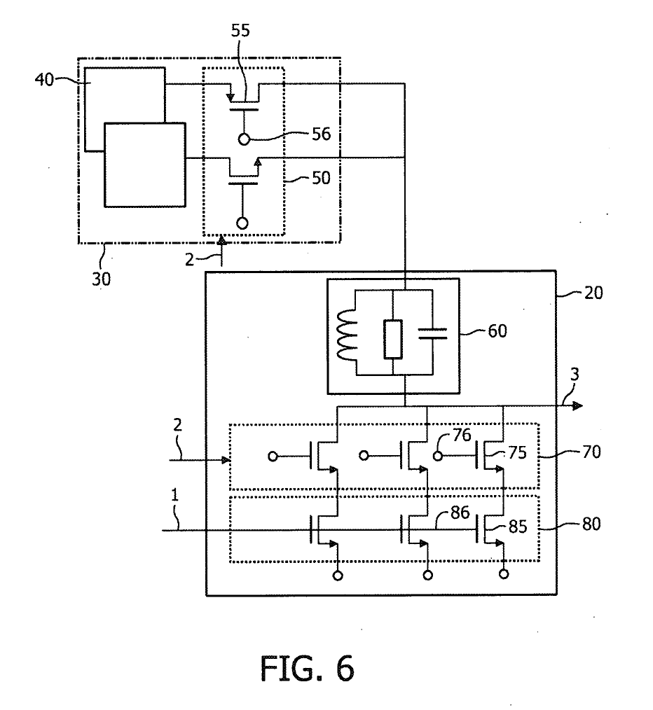

FIG. 6 shows an embodiment of a high efficiency modulating RF amplifier 10 according to claim 3 wherein each one of the current sources 80 comprises a first transistor 85 and each one of the amplitude switches 70 comprises a second transistor 75. The first and second transistor 85, 75 each comprise first and second main electrodes. The first main electrode of each one of the second transistors 75 is coupled to the second main electrode of one of the first transistors 85. The second main electrode of each one of the second transistors 75 is coupled to the output 3.

Each first transistor provides a main current path between a first and second main electrode. Each one of the amplitude switches 70 comprises a second transistor 75, whereby each second transistor 75 provides a main current path between a first and second main electrode. Each one of the current sources 80 is coupled through an amplitude switch 70 to the output 3 of the high efficiency modulating RF amplifier. By serially coupling the two main current paths of a first and a second transistor 85, 75 such that the two main current paths form one longer main current path a modulator 20 has been created having an advantage that it may be designed for field effect transistor technology or may be designed for another kind of technology. A further advantage of this modulator is that it is simple thereby simplifying the design of the high efficiency modulating RF amplifier.

FIG. 6 further shows an embodiment of a high efficiency modulating RF amplifier 10 as defined in claim 4 wherein each one of the plurality of supply switches 50 comprises a third transistor 55. The second and third transistor 75,55 further comprise a control electrode 76, 56 arranged to be under control of the envelope signal 2. By supplying the envelope code 2 to the control electrode 76, 56 of each one of the second and third transistors 75, 55, the second and third transistor is given a digital switching function in a simple way.

The control of the amplitude switches 70 is in dependence of the envelope signal 2. The more amplitude switches 70 are conducting the more output signal is generated. Thus the amount of current provided to the output 3 by the current sources 80 relates to the envelope signal 2. Since the amount of current relates to the amplitude of the output signal provided at the output 3 with a small output signal a small amount of current is conducting thereby increasing the power efficiency of the modulator 20.

In FIG. 6 the supply switches 50 have been implemented as MOSTs. Ideally the supply switches 50 have no resistance, but in a practical implementation each one of the supply switches will have a resistance. Since the power being delivered by each one of the power supply stages 40 may be different the scaling of the MOSTs serving as supply switches may differ. A power supply stage 40 delivering a higher supply voltage may require a smaller series resistance and thus a larger scaled MOST than a power supply stage delivering a lower supply voltage.

The supply switches 50 comprising the third transistors 55 may be implemented using PMOST devices or NMOST devices. In case of a power supply stage 40 providing a lower supply voltage an NMOST device may be used and in case of a power supply stage 40 providing a higher supply voltage a PMOST device may be used. In these cases the choice for either NMOST or PMOST device may be determined by the available voltage to drive the gate electrode 56 of each one of the third transistors 55. The supply switches 50 may also comprise parallel combinations of one or more PMOST and/or one or more NMOST devices.

FIG. 6 further shows an embodiment of a high efficiency modulating RF amplifier 10 according to claim 5 wherein the first transistor 85 further comprises a control electrode 86 for receiving the phase information signal 1. By supplying the phase information to the control electrode 86 of each first transistor 85 the first transistor is given a current source or an amplifying function in a simple way.

The modulator 20 as shown in FIG. 6 may at first sight resemble a Digital to Analogue Converter (DAC) known from the art. With a digital envelope signal 2 the amplitude switches 70 are under control of bits in the digital envelope signal. A difference with the DACs known from the art is however that the current sources 80 are in dependence of the phase information signal 1.

In a further embodiment, not shown in a figure, the modulator 20 further comprises a further output, the output and the further output providing a balanced output signal. The output and the further output may be coupled with a BALUN network to an antenna. This embodiment has the advantage that the influence of a ripple voltage on the operating voltage provided to the modulator 20 caused by the switching of the supply switches 50 and appearing as a common mode voltage at the output and the further output will be suppressed.

In an embodiment of a high efficiency modulating RF amplifier 10 according to claim 6, not shown in a figure, the first main electrode of the first transistor 85 is arranged for receiving the phase information signal 1. Each first transistor 85 is thereby given a current source or an amplifying function in a simple way.

The weighting of the current provided by the first transistors 85 may be binary with the advantage that each one of the second transistors 75 is under control of a bit in the digital envelope signal 2. Also each one of the first transistors 85 may have equal scaling and provide an equal current with the plurality of second transistors 75 being controlled by a thermometer code, the thermometer code being in dependence of the envelope signal 2.

FIG. 6 further shows an embodiment of a high efficiency modulating RF amplifier 10 according to claim 7 wherein the phase information signal 1 comprises a signal with a frequency f₀. The impedance network 60 comprises a parallel coupling of a resistor, an inductor having an inductance and a capacitor having a capacitance. The value of the inductance and capacitance are in dependence of the frequency f₀. The inductance value and the capacitance value are chosen such that the impedance network acts as a resistive pull up for a signal with frequency f₀ that is included in the phase information signal. The impedance network 60 will attenuate signals with other frequencies than f₀. This gives the advantage that the phase information signal is filtered and the signal with frequency f₀ will have the largest amplitude at the output.

In a further embodiment of the high efficiency modulating RF amplifier 10 according to claim 8 at least one of the plurality of power supply stages 40 is a high efficiency power supply stage using a switching technique. An example of such a power supply stage is a DC-DC buck converter.

In a further embodiment of the high efficiency modulating RF amplifier according to claim 9 the power supply 30 comprises one or more DC-DC boost converters. This gives the advantage that in a battery supplied application operating supply voltages higher than the battery voltage may be provided to the modulator 20 thereby increasing the maximal output voltage swing and output power of the high efficiency modulating RF amplifier.

DC-DC converters are well known in the art. DC-DC converters may be implemented using switched capacitors when the required power to be provided is low. For higher power levels pulse-width modulating DC-DC converters comprising LC filter means may be more appropriate.

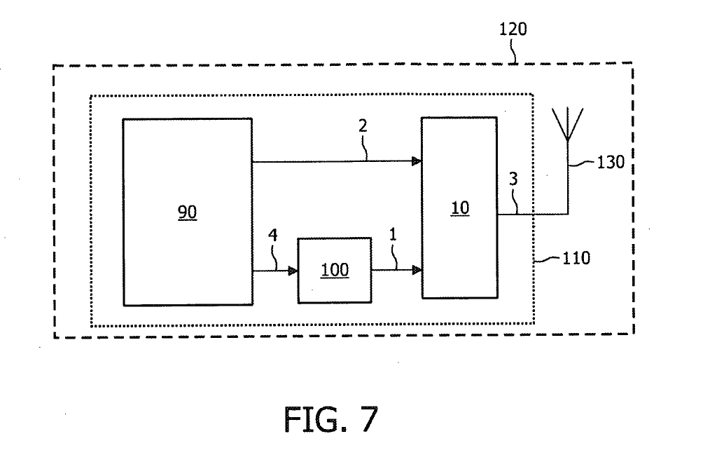

FIG. 7 shows an embodiment of a polar transmitter 110 as defined in claim 10 comprising the high efficiency modulating RF amplifier 10 as defined in any one of claims 1-9. The polar transmitter 110 further comprises:

a circuit 90 for generating a phase/frequency signal and the envelope signal 2, the polar transmitter

an oscillator 100 for receiving the phase/frequency signal and for generating the phase information signal 1.

The circuit 90 for example comprises a digital CORDIC for receiving for example digital in-phase and analogue quadrature information and for generating a digital phase/frequency signal 4 and a digital envelope signal 2. The oscillator 100 may be part of a Phase Locked Loop and is arranged for receiving the digital phase/frequency signal 4 and generating the phase information signal 1. In case of the circuit 90 being an analogue circuit such as an analogue CORDIC, it generates an analogue phase/frequency signal 4 and an analogue envelope signal 2 that may need to be low pass filtered and digitized before being provided to the oscillator 100 and high efficiency modulating RF amplifier 10. The output 3 of the high efficiency RF amplifier is for example coupled to an antenna possibly via one or more components.

An embodiment of a polar transmitter according to claim 10 comprising the high efficiency modulating RF amplifier according to claim 8 has the advantage of an increased efficiency.

A further embodiment of a polar transmitter according to claim 10 comprising the high efficiency modulating RF amplifier according to claim 9 has the advantage of an increased output power.

The device as claimed in claim 11 comprises the polar transmitter as defined in claim 9 or 10. Examples of such a device are mobile phones and wireless interfaces. As these devices may be battery powered the use of a polar transmitter with increased efficiency is advantageous for the operating time. The simplified design of the high efficiency modulating RF amplifier further provides a means for cost reduction.

1. A high efficiency modulating RF amplifier (10) for amplitude modulating a signal defined by a phase information signal (1) and an envelope signal (2), comprising a power supply (30) arranged to provide an operating voltage under control of the envelope signal (2), characterized in that:
the high efficiency modulator RF amplifier further comprises a modulator (20) for receiving the phase information signal (1), the envelope signal (2) and the operating voltage,
the modulator (20) is arranged to provide an output signal of which an amplitude is modulated under control of the envelope signal (2),
the power supply (30) comprises a plurality of power supply stages (40) and a plurality of supply switches (50) coupled between the plurality of power supply stages (40) and the modulator (20),
the power supply (30) is arranged to select one of the power supply stages (40) to provide the operating voltage under control of the envelope signal (2).

2. A high efficiency modulating RF amplifier (10) according to claim 1 wherein the modulator (20) further comprises an impedance network (60) coupled between the power supply (30) and an amplifier output (3), and the modulator (20) further comprising a plurality of amplitude switches (70) coupled between the amplifier output (3) and a plurality of current sources (80), each one of the amplitude switches (70) being under control of the envelope signal (2) and each one of the current sources (80) being arranged to provide a current in dependence of the phase information signal (1).

3. A high efficiency modulating RF amplifier (10) according to claim 2 wherein each one of the current sources (80) comprises a first transistor (85) and each one of the amplitude switches (70) comprising a second transistor (75), the first and second transistor (85, 75) each comprising first and second main electrodes, the first main electrode of each one of the second transistors (75) being coupled to the second main electrode of one of the first transistors (85), the second main electrode of each one of the second transistors (75) being coupled to the amplifier output (3).

4. A high efficiency modulating RF amplifier (10) according to claim 3 wherein each one of the plurality of supply switches (50) comprises a third transistor (55), the second and third transistor (75,55) further comprise a control electrode (76, 56) arranged to be under control of the envelope signal (2).

5. A high efficiency modulating RF amplifier (10) according to claim 4 wherein the first transistor (85) further comprises a control electrode (86) for receiving the phase information signal (1).

6. A high efficiency modulating RF amplifier (10) according to claim 5 wherein the first main electrode of the first transistor (85) is arranged for receiving the phase information signal (1).

7. A high efficiency modulating RF amplifier (10) according to claim 5 wherein the phase information signal (1) comprises a signal with a frequency f₀, the impedance network (60) comprises a parallel coupling of a resistor, an inductor having an inductance and a capacitor having a capacitance, the value of the inductance and capacitance being in dependence of the frequency f₀.

8. A high efficiency modulating RF amplifier (10) according to claim 1 wherein at least one of the plurality of power supply stages (40) is a high efficiency power supply stage using a switching technique.

9. A high efficiency modulating RF amplifier (10) according to claim 8 wherein the high efficiency power supply stage is a boost converter.

10. A polar transmitter (110) comprising the high efficiency modulating RF amplifier (10) as defined in claim 1, wherein the polar transmitter (110) further comprises a circuit (90) for generating a phase/frequency signal (4) and the envelope signal (2), the polar transmitter further comprising an oscillator (100) for receiving the phase/frequency signal (4) and for generating the phase information signal (1).

11. A device (120) comprising the polar transmitter (110) as defined in claim 10.
